(19) United States
(12) Patent Application Publication
(10) Pub. No.: US 2026/0033358 A1
(43) Pub. Date: Jan. 29, 2026

(54) PACKAGE COMPRISING SUBSTRATE WITH VIA INTERCONNECTS COMPRISING NON-CIRCULAR PLANAR CROSS SECTION

(71) Applicant: QUALCOMM Incorporated, San Diego, CA (US)

(72) Inventors: Aniket PATIL, San Diego, CA (US); Joan Rey Villarba BUOT, Escondido, CA (US); Brigham NAVAJA, San Diego, CA (US)

(21) Appl. No.: 18/784,654

(22) Filed: Jul. 25, 2024

(51) Int. Cl. H01L 23/498; H01L 23/00

(52) U.S. Cl. CPC H01L 23/49838; H01L 23/49822; H01L 23/49894; H01L 24/16; H01L 23/49816; H01L 2224/16227

(57) ABSTRACT

A package comprising an integrated device and a substrate coupled to the integrated device, wherein the substrate comprises a plurality of via interconnects, and wherein at least one via interconnect from the plurality of via interconnects comprises a planar cross sectional shape that includes a concave portion.

### FIELD

Various features relate to packages and substrates.

### BACKGROUND

A package may include a substrate and integrated devices. These components are coupled together to provide a package that may perform various electrical functions. The performance of integrated devices and/or packages and its components may depend on various factors, including the number of interconnects in the packages and/or the integrated devices. There is an ongoing need to improve the performance of integrated devices and/or packages, while also improving and keeping the form factor of integrated devices and/or packages as small as possible.

### SUMMARY

Various features relate to packages and substrates.

One example provides a package comprising an integrated device and a substrate coupled to the integrated device, wherein the substrate comprises a plurality of via interconnects, and wherein at least one via interconnect from the plurality of via interconnects comprises a planar cross sectional shape that includes a concave portion.

Another example provides a substrate comprising a first dielectric layer; and a plurality of via interconnects located in the first dielectric layer, wherein at least one via interconnect from the plurality of via interconnects comprises a planar cross sectional shape that includes a concave portion.

Another example provides a method for fabricating a substrate. The method forms a first dielectric layer. The method forms a plurality of via interconnects in the first dielectric layer, wherein at least one via interconnect from the plurality of via interconnects comprises a planar cross sectional shape that includes a concave portion.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional profile view of an exemplary package that includes a substrate with non-circular via interconnects.

FIG. 2 illustrates a close up cross sectional plan view of an exemplary substrate that includes non-circular via interconnects.

FIGS. 3A-3E illustrate an exemplary sequence for fabricating a substrate that includes non-circular via interconnects.

FIG. 4 illustrates an exemplary flow diagram of a method for fabricating a substrate that includes non-circular via interconnects.

FIG. 5 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising an integrated device and a substrate coupled to the integrated device, wherein the substrate comprises a plurality of via interconnects. The plurality of via interconnects includes at least one via interconnect that comprises a planar cross sectional shape that includes a concave portion. This helps improve the current carrying capabilities of the via interconnects, which helps improve the power delivery network (PDN) of the package, while keeping the substrate and/or the package as small as possible.

### Exemplary Package With a Substrate Comprising Interconnects With a Concave Portion

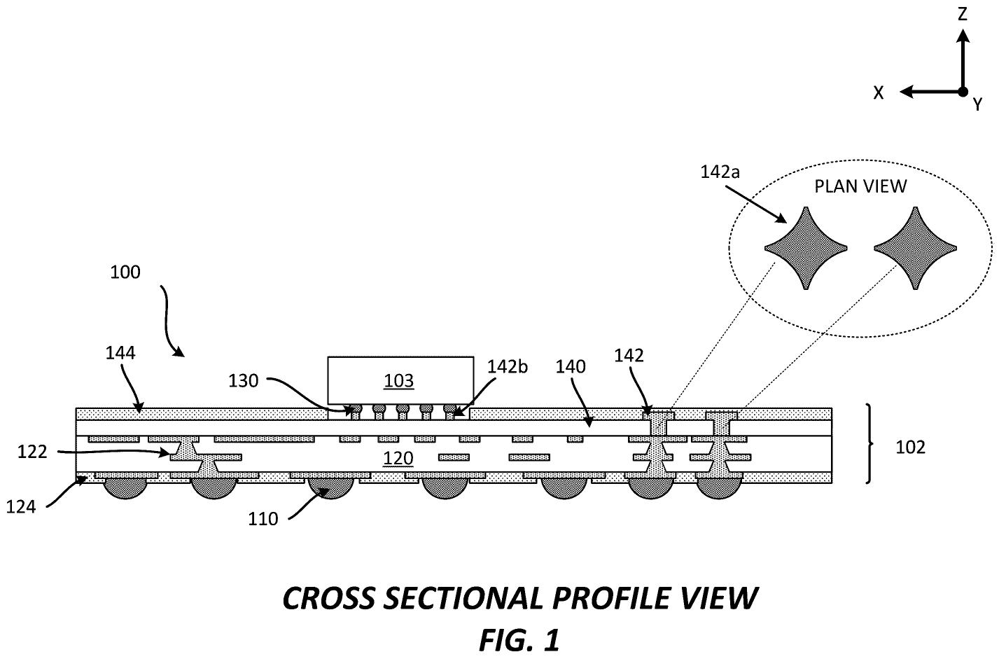

FIG. 1 illustrates a cross sectional profile view of a package 100 that includes an integrated device 103 and a substrate 102 comprising a plurality of vias interconnects, where at least some of the via interconnects have a concave shape, a concave portion, a concave surface and/or a concave side wall surface. The substrate 102 comprises at least one dielectric layer 120, at least one dielectric layer 140, a plurality of interconnects 122, a plurality of interconnects 142, a solder resist layer 124 and a solder resist layer 144. A plurality of solder interconnects 110 is coupled to the substrate 102. For example, the plurality of solder interconnects 110 may be coupled to the plurality of interconnects 122. The solder resist layer 124 may be formed and coupled to a surface of the at least one dielectric layer 120. The solder resist layer 144 may be formed and coupled to a surface of the at least one dielectric layer 140. The at least one dielectric layer 140 is formed and coupled to the at least one dielectric layer 120. In some implementations, the at least one dielectric layer 140 may include a different material from the at least one dielectric layer 120. In one example, the at least one dielectric layer 120 may include prepreg, and the at least one dielectric layer 140 may include polyimide. However, different implementations may include different materials for the at least one dielectric layer 120 and/or the at least one dielectric layer 140.

The plurality of interconnects 122 may be located at least partially in the at least one dielectric layer 120. The plurality of interconnects 142 may be located at least partially in the at least one dielectric layer 140. The plurality of interconnects 142 may be coupled to the plurality of interconnects 122. At least some of the interconnects from the plurality of interconnects 142 are configured to provide electrical paths for power (e.g., first power, second power). In some implementations, at least some of the interconnects from the plurality of interconnects 142 are configured to provide electrical paths for ground. In some implementations, at least some of the interconnects from the plurality of interconnects 142 are configured to provide electrical paths for input/output (I/O) signals.

The plurality of interconnects 142 includes a plurality of interconnects 142a and a plurality of interconnects 142b. The integrated device 103 is coupled to the plurality of interconnects 142b through a plurality of solder interconnects 130. The plurality of interconnects 142b is coupled to the plurality of interconnects 142a. The plurality of interconnects 142a may include a plurality of via interconnects. The plurality of interconnects 142a may include at least one via interconnect that has non-circular shape, a concave shape, a concave portion, a concave surface and/or a concave side wall surface. The plurality of interconnects 142a may include at least one via interconnect that has a star shape (e.g., star shape comprising a concave portion) or a cross shape (e.g., cross shape comprising a concave portion). The plurality of interconnects 142a may include at least one pad interconnect that has a non-circular shape, a concave shape, a concave portion, a concave surface and/or a concave side wall surface. In some implementations, the plurality of interconnects 142a may include at least one via interconnect that has a non-circular shape, a concave shape, a concave portion, a concave surface and/or a concave side wall surface, where the via interconnects are coupled to and touch pad interconnects that have non-circular shape, a concave shape, a concave portion, a concave surface and/or a concave side wall surface.

In some implementations, one or more interconnects from the plurality of interconnects 142a may be configured to provide one or more electrical paths for ground. In some implementations, one or more interconnects from the plurality of interconnects 142a may be configured to provide one or more electrical paths for power (e.g., first power, second power, third power).

At least one interconnect from the plurality of interconnects 142a has a planar cross section that is greater than the planar cross section of at least one interconnect from the plurality of interconnects with circular planar cross section, while maintaining the same minimum spacing and/or pitch between interconnects. A circular shape and/or circular planar cross section may include a convex shape, a convex portion and/or a convex surface. The increase in the size of the planar cross section means that the plurality of interconnects 142a has increased current carrying capacity, which helps improve the power delivery network (PDN) of the substrate 102 and/or the package 100, while maintaining and/or reducing the overall size of the substrate 102 and/or the package 100. In some implementations, the use of interconnects with planar cross sections that are circular and interconnects with planar cross sections that are non-circular helps provide optimal performance of the integrated device, the substrate 102 and/or the package 100.

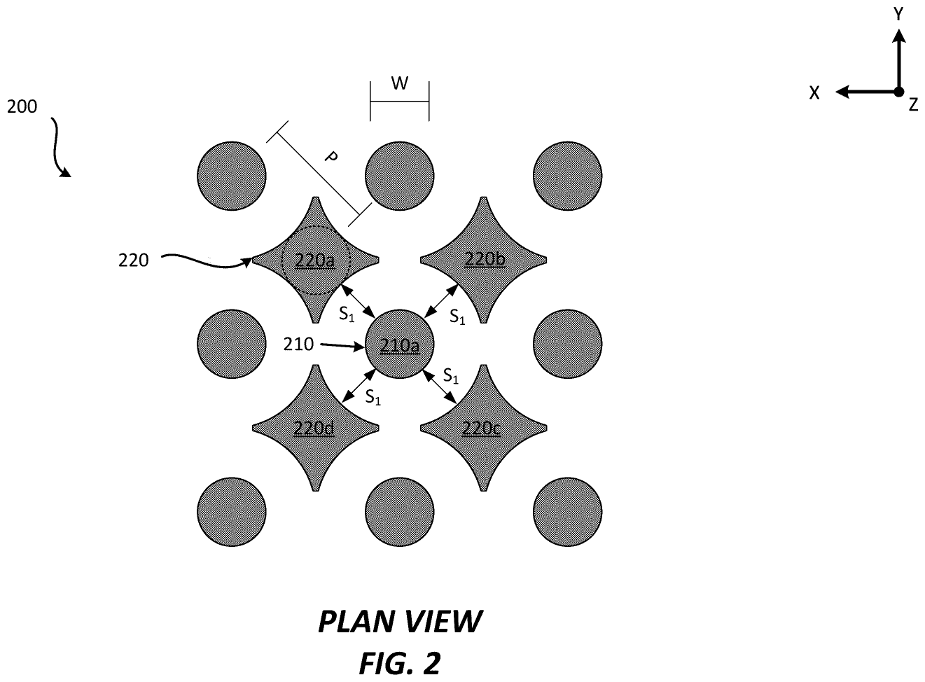

FIG. 2 illustrates a close up plan view of a substrate 200 that includes a plurality of interconnects 210 and a plurality of interconnects 220. The substrate 200 may be an exemplary representation of the substrate 102. The plurality of interconnects 210 and/or the plurality of interconnects 220 may be a representation of the plurality of interconnects 142 of the substrate 102. For example, the plurality of interconnects 210 and/or the plurality of interconnects 220 may be a representation of the plurality of interconnects 142a of the substrate 102.

As shown in FIG. 2, in some implementations, the plurality of interconnects 210 may be interleaved with the plurality of interconnects 220. For example, a row of interconnects from the plurality of interconnects 220 may be located between a first row and a second row of interconnects from the plurality of interconnects 210. In some implementations, a row of interconnects from the plurality of interconnects 210 may be located between a first row and a second row of interconnects from the plurality of interconnects 220. In some implementations, interleaving the plurality of interconnects 210 and the plurality of interconnects 220 helps provide optimal performance of the substrate 200, the integrated device 103 and/or the package 100.

In some implementations, at least one interconnect from the plurality of interconnects 210 may include a planar cross section (e.g., along X-Y plane) that is circular (e.g., circular planar cross sectional shape) and/or approximately circular. As described above, at least one interconnect from the plurality of interconnects 220 may include a planar cross section (e.g., planar cross sectional shape) that includes a concave shape and/or a concave portion. For example, the side walls of one or more interconnects from the plurality of interconnects 220 may include a concave shaped wall (e.g., first concave shaped wall, second concave shaped wall., third concave shaped wall, fourth concave shaped wall) and/or a concave surface (e.g., first concave surface, second concave surface, third concave surface, fourth concave surface). As used in the disclosure, a plurality of interconnects that includes a concave shaped wall, a concave shape, a concave portion and/or a concave surface may mean that at least one interconnect from the plurality of interconnects includes at least one concave shaped wall, at least one concave shape, at least one concave portion and/or at least one concave surface.

In some implementations, one or more interconnects from the plurality of interconnects 210 may be configured to provide one or more electrical paths for ground. In some implementations, one or more interconnects from the plurality of interconnects 220 may be configured to provide one or more electrical paths for power (e.g., first power, second power, third power).

As mentioned above, the increase in the size of the planar cross section means that the plurality of interconnects 220 has increased current carrying capacity, which helps improve the power delivery network (PDN) of the substrate 200 and/or the package 100, while maintaining and/or reducing the overall size of the substrate 200 and/or the package 100. In some implementations, the use of interconnects with planar cross sections that are circular and interconnects with planar cross sections that are non-circular helps provide optimal performance of the integrated device, the substrate 200 and/or the package 100. Moreover, the increase in the size of the planar cross section of the plurality of interconnects 220 means improved thermal conductivity and/or heat dissipation through the substrate 200, which can help improve the overall thermal performance of a package.

An interconnect from the plurality of interconnects 210 may have a width (e.g., minimum width, W). A pitch (e.g., minimum pitch, P) may be between (i) an interconnect from the plurality of interconnects 210 and (ii) an interconnect from the plurality of interconnects 220. FIG. 2 also illustrates that an interconnect 210a from the plurality of interconnects 210 (which has a circular planar cross section) has a spacing (S1) (e.g., uniform spacing) to adjacent interconnects from the plurality of the interconnects 220 (which has a non-circular planar cross section). For example, an interconnect 210a from the plurality of interconnects 210 is adjacent to four interconnects (e.g., 220a, 220b, 220c, 220d) from the plurality of interconnects 220. The four interconnects from the plurality of interconnects 220, each includes a concave portion and/or concave surface that faces in the direction of the interconnect 210a from the plurality of interconnects 210. The concave surface of the interconnect 220a is located at a spacing (S1) from the surface of the interconnect 210a. The concave surface of the interconnect 220b is located at a spacing (S1) from the surface of the interconnect 210a. The concave surface of the interconnect 220c is located at a spacing (S1) from the surface of the interconnect 210a. The concave surface of the interconnect 220d is located at a spacing (S1) from the surface of the interconnect 210a.

In some implementations, the plurality of interconnects 210 may represent via interconnects. In some implementations, the plurality of interconnects 220 may represent via interconnects. In some implementations, at least one via interconnect may have a circular planar cross section and at least one other via interconnect may have a non-circular planar cross section (e.g., a concave shaped wall, a concave shape, a concave portion and/or a concave surface). In some implementations, a planar cross section may be along the X-Y plane.

In some implementations, the plurality of interconnects 210 may represent pad interconnects. In some implementations, the plurality of interconnects 220 may represent pad interconnects. In some implementations, at least one pad interconnect may have a circular planar cross section and at least one other pad interconnect may have a non-circular planar cross section (e.g., a concave shaped wall, a concave shape, a concave portion and/or a concave surface). In some implementations, a pad interconnect that includes a non-circular planar cross section may be coupled to a via interconnect that includes a non-circular planar cross section. In some implementations, a pad interconnect that includes a circular planar cross section may be coupled to a via interconnect that includes a non-circular planar cross section.

At least one interconnect from the plurality of interconnects 220 has a planar cross section that is greater than the planar cross section of at least one interconnect from the plurality of interconnects 210 (which have a circular planar cross section), while maintaining the same minimum spacing and/or pitch between interconnects. The increase in the size of the planar cross section means that the plurality of interconnects 220 has increased current carrying capacity, which helps improve the power delivery network (PDN) of the substrate 200 and/or the package, while maintaining and/or reducing the overall size of the substrate 200 and/or the package.

An integrated device (e.g., 103) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G). The packages (e.g., 100) may be configured to support Global System for Mobile (GSM) Communications, Universal Mobile Telecommunications System (UMTS), and/or Long-Term Evolution (LTE). The packages (e.g., 400) may be configured to transmit and receive signals having different frequencies and/or communication protocols.

### Exemplary Sequence for Fabricating a Substrate

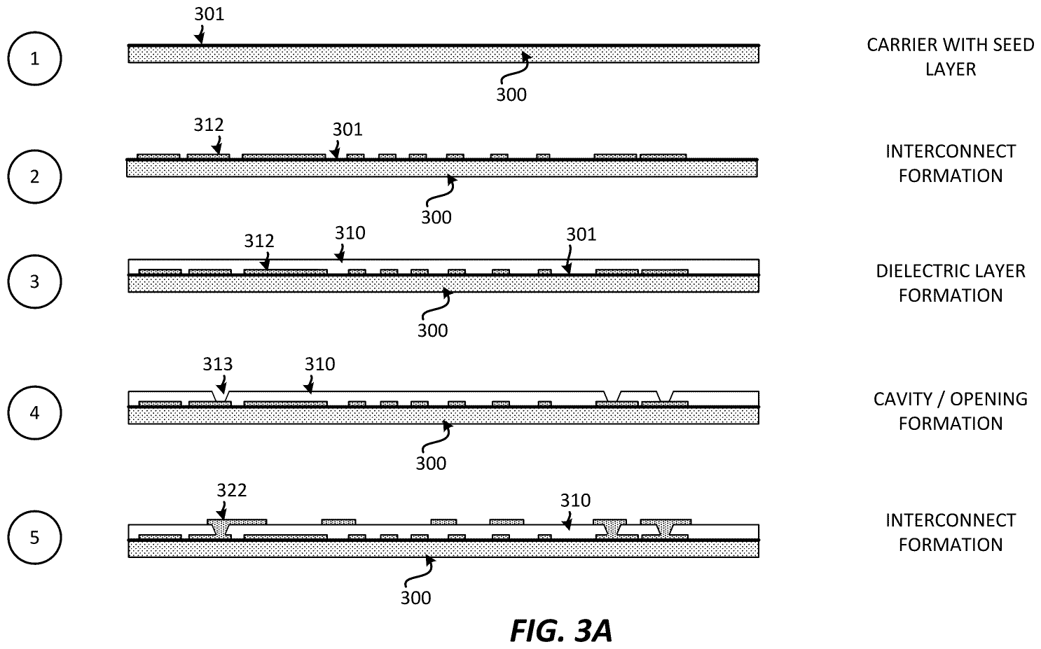

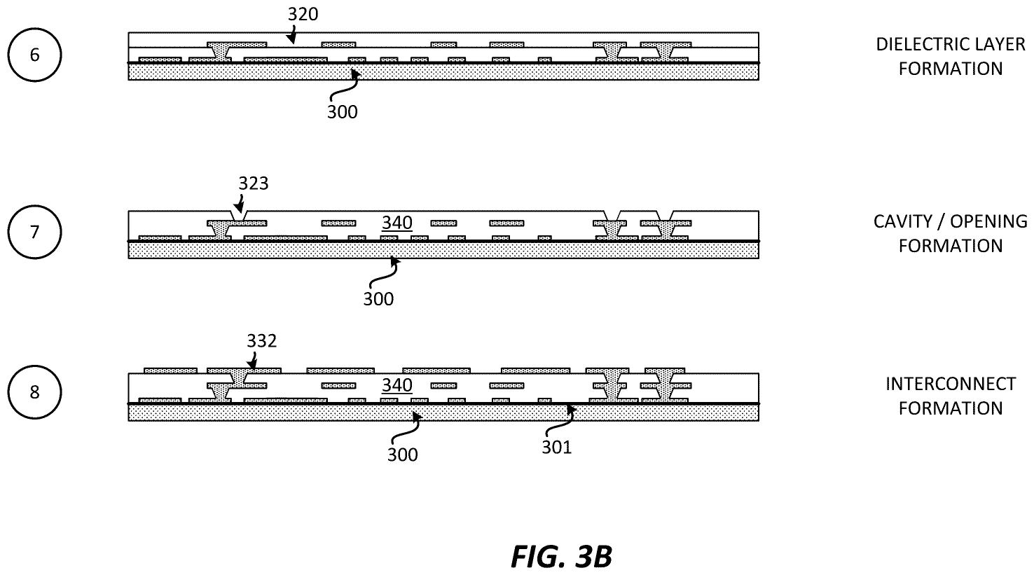

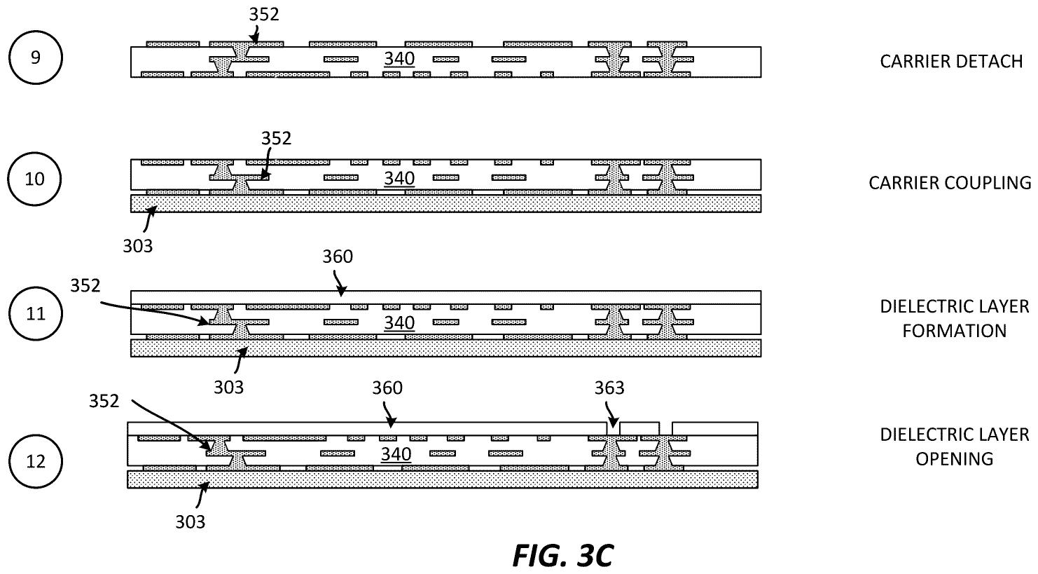

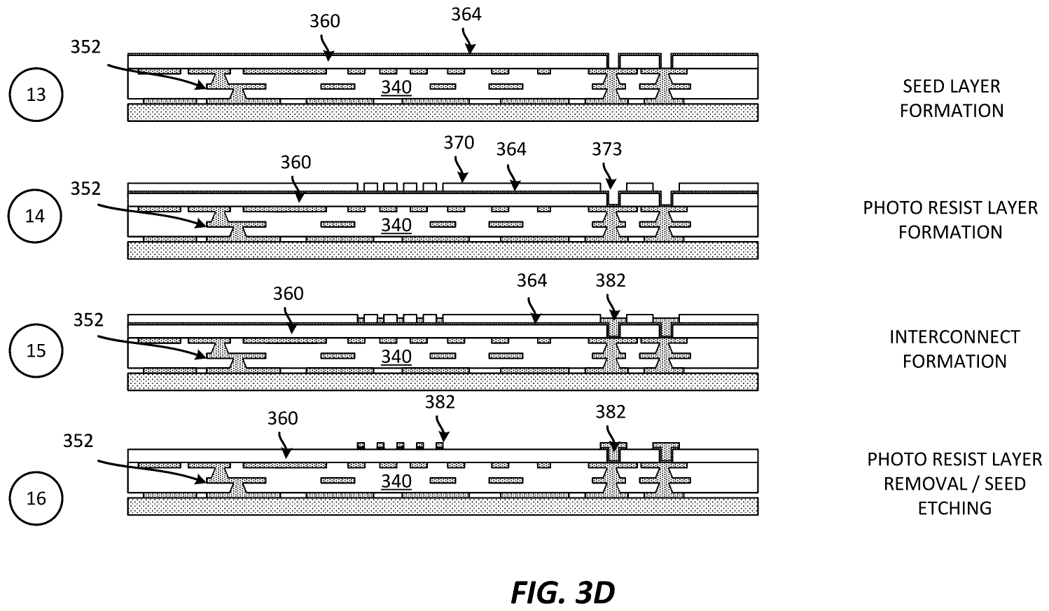

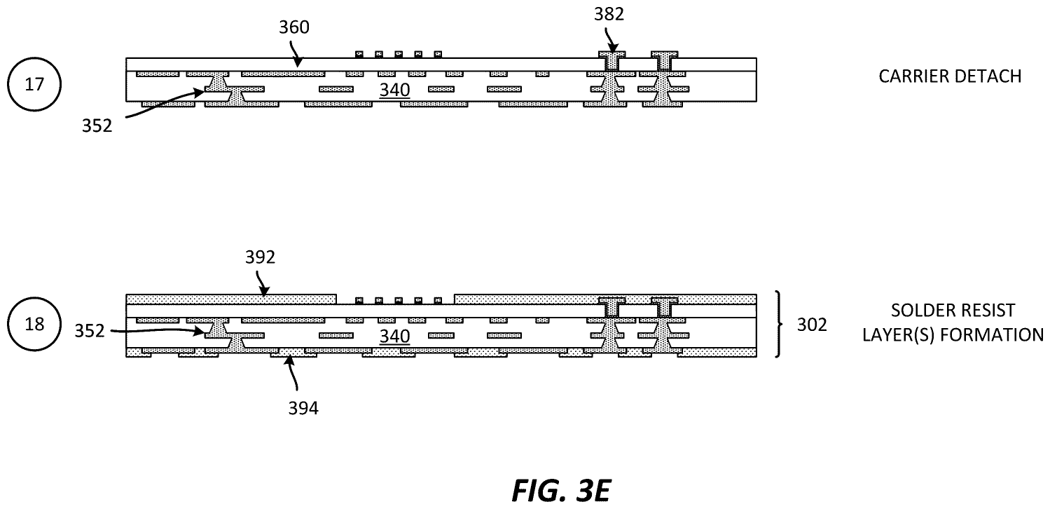

In some implementations, fabricating a substrate includes several processes. FIGS. 3A-3E illustrate an exemplary sequence for providing or fabricating a substrate. In some implementations, the sequence of FIGS. 3A-3E may be used to provide or fabricate the substrate 102. However, the process of FIGS. 3A-3E may be used to fabricate any of the substrates described in the disclosure.

It should be noted that the sequence of FIGS. 3A-3E may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.
Stage 1, as shown in FIG. 3A, illustrates a state after a carrier 300 is provided. A seed layer 301 may be located over the carrier 300.
Stage 2 illustrates a state after a plurality of interconnects 312 are formed. The plurality of interconnects 312 may be located over the seed layer 301. A lithography process, a plating process, a strip process and/or an etching process may be used to form the plurality of interconnects 312. The interconnects 312 may represent at least some of the interconnects from the plurality of interconnects 122.
Stage 3 illustrates a state after a dielectric layer 310 is formed over the carrier 300, the seed layer 301 and the plurality of interconnects 312. A deposition and/or lamination process may be used to form the dielectric layer 310. The dielectric layer 310 may include prepreg and/or polyimide (e.g., polyimide layer). The dielectric layer 310 may include a photo-imageable dielectric. However, different implementations may use different materials for the dielectric layer.
Stage 4 illustrates a state after a plurality of cavities 313 is formed in the dielectric layer 310. The plurality of cavities 313 may be formed using an etching process (e.g., photo etching process), a laser process, an exposure process and/or a development process.
Stage 5 illustrates a state after a plurality of interconnects 322 are formed in and over the dielectric layer 310, including in and over the plurality of cavities 313. For example, a via, pad and/or traces may be formed. The plurality of interconnects 322 may be coupled to the plurality of interconnects 312. A lithography process, a plating process, a strip process and/or an etching process may be used to form the interconnects.
Stage 6, as shown in FIG. 3B, illustrates a state after a dielectric layer 320 is formed over the dielectric layer 310 and the plurality of interconnects 322. A deposition and/or lamination process may be used to form the dielectric layer 320. The dielectric layer 320 may include prepreg and/or polyimide. The dielectric layer 320 may include a photo-imageable dielectric. However, different implementations may use different materials for the dielectric layer.
Stage 7, illustrates a state after a plurality of cavities 323 is formed in the dielectric layer 340. The dielectric layer 340 may represent the dielectric layer 310 and/or the dielectric layer 320. The plurality of cavities 323 may be formed using an etching process (e.g., photo etching process), a laser process, an exposure process and/or a development process.
Stage 8 illustrates a state after a plurality of interconnects 332 are formed in and over the dielectric layer 340, including in and over the plurality of cavities 323. For example, a via, pad and/or traces may be formed. A lithography process, a plating process, a strip process and/or an etching process may be used to form the interconnects.
Stage 9, as shown in FIG. 3C, illustrates a state after the carrier 300 is decoupled (e.g., detached, removed, grinded out) from at least one dielectric layer 340 and the seed layer 301, portions of the seed layer 301 are removed (e.g., etched out), leaving the substrate that includes at least one dielectric layer 340 and the plurality of interconnects 352. The plurality of interconnects 352 may represent the plurality of interconnects 312, the plurality of interconnects 322 and/or the plurality of interconnects 332.
Stage 10 illustrates a state after the dielectric layer 340 is coupled to the carrier 303. An adhesive (not shown) may be used to couple the dielectric layer 340 to the carrier 303. The carrier 303 may include glass.
Stage 11 illustrates a state after a dielectric layer 360 is formed over the dielectric layer 340 and the plurality of interconnects 352. A deposition and/or lamination process may be used to form the dielectric layer 360. The dielectric layer 360 may include polyimide (e.g., polyimide layer). The dielectric layer 360 may include a photo-imageable dielectric. However, different implementations may use different materials for the dielectric layer.
Stage 12 illustrates a state after a plurality of cavities 363 are formed in the dielectric layer 360. The plurality of cavities 363 may be formed using an etching process (e.g., photo etching process), a laser process, an exposure process and/or a development process. The plurality of cavities 363 may include non-circular planar openings (e.g., openings with a concave shape and/or concave portion).
Stage 13, as shown in FIG. 3D, illustrates a state after a seed layer 364 is formed over the dielectric layer 360 and over the plurality of interconnects 352. A sputtering process may be used to form the seed layer 364. The seed layer 364 may include a copper seed.
Stage 14 illustrates a state after a photo resist layer 370 is formed over the seed layer 364. The photo resist layer 370 may include a plurality of openings 373. A deposition process may be used to form the photo resist layer 370. The plurality of openings 373 may include non-circular planar openings (e.g., openings with a concave shape and/or concave portion) and/or circular planar openings.
Stage 15 illustrates a state after a plurality of interconnects 382 are formed in and over the seed layer 364 and the dielectric layer 360, including in and over the plurality of cavities 363 and the plurality of openings 373. For example, a via, pad and/or traces may be formed. A lithography process, a plating process, a strip process and/or an etching process may be used to form the interconnects. Some of the interconnects from the plurality of interconnects 383 may include via interconnects that include a concave shaped wall (e.g., first concave shaped wall, second concave shaped wall, third concave shaped wall, fourth concave shaped wall) and/or a concave surface (e.g., first concave surface, second concave surface, third concave surface, fourth concave surface). Some of the interconnects from the plurality of interconnects 383 may include pad interconnects that include a concave shaped wall (e.g., first concave shaped wall, second concave shaped wall, third concave shaped wall, fourth concave shaped wall) and/or a concave surface (e.g., first concave surface, second concave surface, third concave surface, fourth concave surface). Some of the interconnects from the plurality of interconnects 383 may include pad interconnects with a circular planar cross section. Some of the interconnects from the plurality of interconnects 383 may include via interconnects with a circular planar cross section.
Stage 16 illustrates a state after the photo resist layer 370 and portions of the seed layer 301 are removed (e.g., etched out). A strip process and an etching process may be used to remove the photo resist layer 370 and portions of the seed layer 364. In some implementations, any remaining seed layer from the seed layer 364 may be considered part of the plurality of interconnects 382. In some implementations, the plurality of interconnects 352 may represent the plurality of interconnects 122. In some implementations, the at least one dielectric layer 340 may represent the at least one dielectric layer 120. In some implementations, the plurality of interconnects 382 may represent the plurality of interconnects 142. In some implementations, the at least one dielectric layer 360 may represent the at least one dielectric layer 140.
Stage 17, as shown in FIG. 3E, illustrates a state after the carrier 303 is decoupled (e.g., detached, removed, grinded out) from at least one dielectric layer 340 and/or the plurality of interconnects 352.
Stage 18 illustrates a state after the solder resist layer 392 is formed over the first surface of the substrate 302, and after the solder resist layer 394 is formed over the second surface of the substrate 302. A deposition process and/or lamination process may be used to form the solder resist layer 392 and/or the solder resist layer 394. The solder resist layer 392 and/or the solder resist layer 394 may include openings. An etching process, an exposure process and/or a development process may be used to form the openings in the solder resist layer 392 and/or the openings in the solder resist layer 394. In some implementations, the substrate 302 may represent the substrate 102.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Substrate

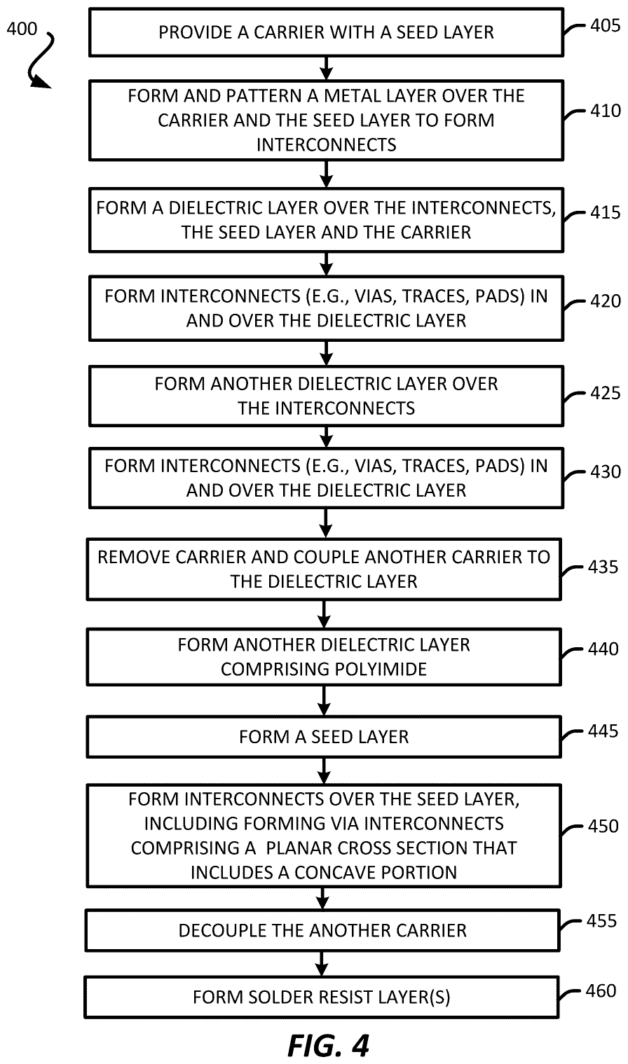

In some implementations, fabricating a substrate includes several processes. FIG. 4 illustrates an exemplary flow diagram of a method 400 for providing or fabricating a substrate. In some implementations, the method 400 of FIG. 4 may be used to provide or fabricate the substrate(s) of the disclosure. For example, the method 400 of FIG. 4 may be used to fabricate the substrate 102.

It should be noted that the method 400 of FIG. 4 may combine one or more processes in order to simplify and/or clarify the method for providing or fabricating a substrate. In some implementations, the order of the processes may be changed or modified.

The method provides (at 405) a carrier with a seed layer. Stage 1 of FIG. 3A, illustrates and describes an example of a state after a carrier 300 is provided. A seed layer 301 may be located over the carrier 300.

The method forms and patterns (at 410) a plurality of interconnects. Stage 2 of FIG. 3A, illustrates and describes an example of a state after a plurality of interconnects 312 are formed. The plurality of interconnects 312 may be located over the seed layer 301. A lithography process, a plating process, a strip process and/or an etching process may be used to form the plurality of interconnects 312. The interconnects 312 may represent at least some of the interconnects from the plurality of interconnects 122.

The method forms (at 415) a dielectric layer. Stage 3 of FIG. 3A, illustrates and describes an example of a state after a dielectric layer 310 is formed over the carrier 300, the seed layer 301 and the plurality of interconnects 312. A deposition and/or lamination process may be used to form the dielectric layer 310. The dielectric layer 310 may include prepreg and/or polyimide (e.g., polyimide layer). The dielectric layer 310 may include a photo-imageable dielectric. However, different implementations may use different materials for the dielectric layer.

The method forms (at 420) a plurality of interconnects. Forming a plurality of interconnects may including forming a plurality of cavities in a dielectric layer and a performing a plating process. Stage 4 of FIG. 3A, illustrates and describes an example of a state after a plurality of cavities 313 is formed in the dielectric layer 310. The plurality of cavities 313 may be formed using an etching process (e.g., photo etching process), a laser process, an exposure process and/or a development process.

Stage 5 of FIG. 3A, illustrates and describes an example of a state after a plurality of interconnects 322 are formed in and over the dielectric layer 310, including in and over the plurality of cavities 313. For example, a via, pad and/or traces may be formed. The plurality of interconnects 322 may be coupled to the plurality of interconnects 312. A lithography process, a plating process, a strip process and/or an etching process may be used to form the interconnects.

The method forms (at 425) another dielectric layer. Stage 6 of FIG. 3B, illustrates and describes an example of a state after a dielectric layer 320 is formed over the dielectric layer 310 and the plurality of interconnects 322. A deposition and/or lamination process may be used to form the dielectric layer 320. The dielectric layer 320 may include prepreg and/or polyimide. The dielectric layer 320 may include a photo-imageable dielectric. However, different implementations may use different materials for the dielectric layer.

The method forms (at 430) a plurality of interconnects. Forming a plurality of interconnects may including forming a plurality of cavities in a dielectric layer and a performing a plating process. Stage 7 of FIG. 3B, illustrates and describes an example of a state after a plurality of cavities 323 are formed in the dielectric layer 340. The dielectric layer 340 may represent the dielectric layer 310 and/or the dielectric layer 320. The plurality of cavities 323 may be formed using an etching process (e.g., photo etching process), a laser process, an exposure process and/or a development process.

Stage 8 of FIG. 3B, illustrates and describes an example of a state after a plurality of interconnects 332 are formed in and over the dielectric layer 340, including in and over the plurality of cavities 323. For example, a via, pad and/or traces may be formed. A lithography process, a plating process, a strip process and/or an etching process may be used to form the interconnects.

The method decouples (at 435) a carrier and couples another carrier to the dielectric layer 340. Stage 9 of FIG. 3C, illustrates and describes an example of a state after the carrier 300 is decoupled (e.g., detached, removed, grinded out) from at least one dielectric layer 340 and the seed layer 301, portions of the seed layer 301 are removed (e.g., etched out), leaving the substrate that includes at least one dielectric layer 340 and the plurality of interconnects 352. The plurality of interconnects 352 may represent the plurality of interconnects 312, the plurality of interconnects 322 and/or the plurality of interconnects 332.

Stage 10 of FIG. 3C, illustrates and describes an example of a state after the dielectric layer 340 is coupled to the carrier 303. An adhesive (not shown) may be used to couple the dielectric layer 340 to the carrier 303. The carrier 303 may include glass.

The method forms (at 440) another dielectric layer. Stage 11 of FIG. 3C, illustrates and describes an example of a state after a dielectric layer 360 is formed over the dielectric layer 340 and the plurality of interconnects 352. A deposition and/or lamination process may be used to form the dielectric layer 360. The dielectric layer 360 may include polyimide (e.g., polyimide layer). The dielectric layer 360 may include a photo-imageable dielectric. However, different implementations may use different materials for the dielectric layer. Forming the dielectric layer may also include forming a plurality of cavities in the dielectric layer. Stage 12 of FIG. 3C, illustrates a state after a plurality of cavities 363 are formed in the dielectric layer 360. The plurality of cavities 363 may be formed using an etching process (e.g., photo etching process), a laser process, an exposure process and/or a development process. The plurality of cavities 363 may include non-circular planar openings (e.g., openings with a concave shape and/or concave portion).

Th method forms (at 445) a seed layer. Stage 13 of FIG. 3D, illustrates and describes an example of a state after a seed layer 364 is formed over the dielectric layer 360 and over the plurality of interconnects 352. A sputtering process may be used to form the seed layer 364. The seed layer 364 may include a copper seed.

The method forms (at 450) a plurality of interconnects in the at least dielectric layer, where some of the interconnects may include a concave shaped wall (e.g., first concave shaped wall, second concave shaped wall, third concave shaped wall, fourth concave shaped wall) and/or a concave surface (e.g., first concave surface, second concave surface, third concave surface, fourth concave surface).

Stage 14 of FIG. 3D, illustrates and describes an example of a state after a photo resist layer 370 is formed over the seed layer 364. The photo resist layer 370 may include a plurality of openings 373. A deposition process may be used to form the photo resist layer 370. The plurality of openings 373 may include non-circular planar openings (e.g., openings with a concave shape and/or concave portion) and/or circular planar openings.

Stage 15 of FIG. 3D, illustrates and describes an example of a state after a plurality of interconnects 382 are formed in and over the seed layer 364 and the dielectric layer 360, including in and over the plurality of cavities 363 and the plurality of openings 373. For example, a via, pad and/or traces may be formed. A lithography process, a plating process, a strip process and/or an etching process may be used to form the interconnects. Some of the interconnects from the plurality of interconnect 383 may include via interconnects with a planar cross sectional shape that includes a concave shaped wall (e.g., first concave shaped wall, second concave shaped wall, third concave shaped wall, fourth concave shaped wall) and/or a concave surface (e.g., first concave surface, second concave surface, third concave surface, fourth concave surface). Some of the interconnects from the plurality of interconnects 383 may include pad interconnects with a planar cross sectional shape that includes a concave shaped wall (e.g., first concave shaped wall, second concave shaped wall, third concave shaped wall, fourth concave shaped wall) and/or a concave surface (e.g., first concave surface, second concave surface, third concave surface, fourth concave surface). Some of the interconnects from the plurality of interconnects 383 may include pad interconnects with a circular planar cross section (e.g., circular planar cross sectional shape). Some of the interconnects from the plurality of interconnects 383 may include via interconnects with a circular planar cross section (e.g., circular planar cross sectional shape).

Stage 16 of FIG. 13D, illustrates and describes an example of a state after the photo resist layer 370 and portions of the seed layer 301 are removed (e.g., etched out). A strip process and an etching process may be used to remove the photo resist layer 370 and portions of the seed layer 364. In some implementations, any remaining seed layer from the seed layer 364 may be considered part of the plurality of interconnects 382. In some implementations, the plurality of interconnects 352 may represent the plurality of interconnects 122. In some implementations, the at least one dielectric layer 340 may represent the at least one dielectric layer 120. In some implementations, the plurality of interconnects 382 may represent the plurality of interconnects 142. In some implementations, the at least one dielectric layer 360 may represent the at least one dielectric layer 140.

The method decouples (at 455) the carrier. Stage 17 of FIG. 3E, illustrates and describes an example of a state after the carrier 303 is decoupled (e.g., detached, removed, grinded out) from at least one dielectric layer 340 and/or the plurality of interconnects 352.

The method forms (at 460) solder resist layers. Stage 18 of FIG. 3E, illustrates and describes an example of a state after the solder resist layer 392 is formed over the first surface of the substrate 302, and after the solder resist layer 394 is formed over the second surface of the substrate 302. A deposition process and/or lamination process may be used to form the solder resist layer 392 and/or the solder resist layer 394. The solder resist layer 392 and/or the solder resist layer 394 may include openings. An etching process, an exposure process and/or a development process may be used to form the openings in the solder resist layer 392 and/or the openings in the solder resist layer 394. In some implementations, the substrate 302 may represent the substrate 102.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

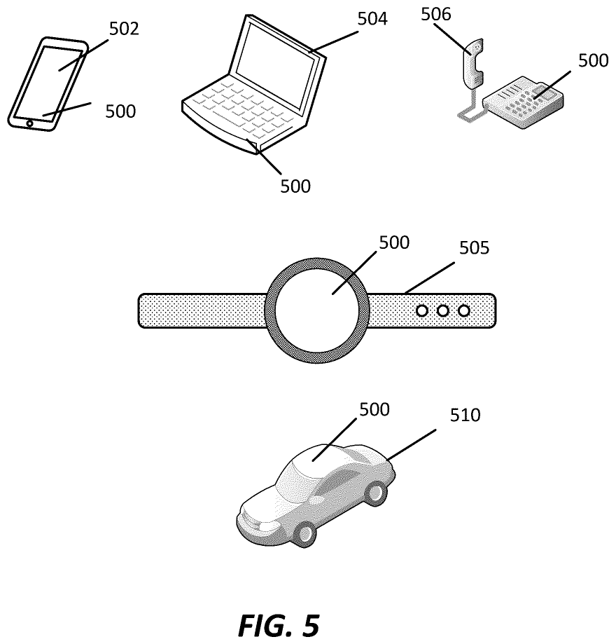

FIG. 5 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 502, a laptop computer device 504, a fixed location terminal device 506, a wearable device 508, or automotive vehicle 510 may include a device 500 as described herein. The device 500 may be, for example, any of the devices and/or integrated circuit (IC) packages described herein. The devices 502, 504, 506 and 508 and the vehicle 510 illustrated in FIG. 5 are merely exemplary. Other electronic devices may also feature the device 500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IOT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-2, 3A-3E, and 4-5 may be rearranged and/or combined into a single component, process, feature or function or embodied in several components, processes, or functions. Additional elements, components, processes, and/or functions may also be added without departing from the disclosure. It should also be noted FIGS. 1-2, 3A-3E, and 4-5 and its corresponding description in the present disclosure is not limited to dies and/or ICs. In some implementations, FIGS. 1-2, 3A-3E, and 4-5 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.
Aspect 1: A package comprising an integrated device; and a substrate coupled to the integrated device, wherein the substrate comprises a plurality of via interconnects, and wherein at least one via interconnect from the plurality of via interconnects comprises a planar cross sectional shape that includes a concave portion.
Aspect 2: The package of aspect 1, wherein the plurality of via interconnects comprises at least one via interconnect with a concave shaped wall.
Aspect 3: The package of aspect 1, wherein the plurality of via interconnects comprises at least one via interconnect with a planar cross sectional shape that includes a cross shape and/or a star shape.
Aspect 4: The package of aspects 1 through 3, wherein the plurality of via interconnects are configured to provide at least one electrical path for power.
Aspect 5: The package of aspects 1 through 4, wherein the plurality of via interconnects includes a first plurality of via interconnects, and wherein the substrate further comprises a second plurality of via interconnects comprising at least one via interconnect with a planar cross sectional shape that includes a circular shape.
Aspect 6: The package of aspect 5, wherein the first plurality of via interconnects and the second plurality of via interconnects are arranged in an interleaved manner.
Aspect 7: The package of aspects 5 through 6, wherein a first via interconnect from the first plurality of via interconnects includes a first planar area, and wherein a second via interconnect from the second plurality of via interconnects includes a second planar area that is less than the first planar area of the first via interconnect.
Aspect 8: The package of aspects 1 through 7, wherein the substrate includes a polyimide layer, and wherein the plurality of via interconnects are located in the polyimide layer.
Aspect 9: The package of aspect 8, wherein the substrate further comprises a plurality of pad interconnects coupled to the plurality of via interconnects.
Aspect 10: The package of aspects 8 through 9, wherein the substrate further comprises a dielectric layer that is a different material from the polyimide layer, and wherein the dielectric layer is coupled to the polyimide layer.
Aspect 11: A substrate comprising a first dielectric layer; and a plurality of via interconnects located in the first dielectric layer, wherein at least one via interconnect from the plurality of via interconnects comprises a planar cross sectional shape that includes a concave portion.
Aspect 12: The substrate of aspect 11, wherein the plurality of via interconnects comprises at least one via interconnect with a concave shaped wall.
Aspect 13: The substrate of aspect 11, wherein the plurality of via interconnects comprises at least one via interconnect with a planar cross sectional shape that includes a cross shape and/or a star shape.
Aspect 14: The substrate of aspects 11 through 13, wherein the plurality of via interconnects are configured to provide at least one electrical path for power.
Aspect 15: The substrate of aspects 11 through 14, wherein the plurality of via interconnects includes a first plurality of via interconnects, and wherein the substrate further comprises a second plurality of via interconnects comprising a planar cross sectional shape that includes a circular shape.
Aspect 16: The substrate of aspect 15, wherein the first plurality of via interconnects and the second plurality of via interconnects are arranged in an interleaved manner.
Aspect 17: The substrate of aspects 15 through 16, wherein a first via interconnect from the first plurality of via interconnects includes a first planar area, and wherein a second via interconnect from the second plurality of via interconnects includes a second planar area that is less than the first planar area of the first via interconnect.
Aspect 18: The substrate of aspects 11 through 17, wherein the first dielectric layer includes a polyimide layer.
Aspect 19: The substrate of aspect 18, further comprising a plurality of pad interconnects coupled to the plurality of via interconnects.
Aspect 20: The substrate of aspects 18 through 19, further comprising a second dielectric layer that includes a different material from the first dielectric layer, wherein the second dielectric layer is coupled to the polyimide layer.
Aspect 21: A method for fabricating a substrate. The method forms a first dielectric layer. The method forms a plurality of via interconnects in the first dielectric layer, wherein at least one via interconnect from the plurality of via interconnects comprises a planar cross sectional shape that includes a concave portion.
Aspect 22: The method of aspect 21, wherein the plurality of via interconnects comprises at least one via interconnect with a concave shaped wall.
Aspect 23: The method of aspect 21, wherein the plurality of via interconnects comprises at least one via interconnect with a planar cross sectional shape that includes a cross shape and/or a star shape.
Aspect 24: The method of aspects 21 through 23, wherein the plurality of via interconnects are configured to provide at least one electrical path for power.
Aspect 25: The method of aspects 21 through 24, wherein the plurality of via interconnects includes a first plurality of via interconnects, and wherein the substrate further comprises a second plurality of via interconnects comprising a planar cross sectional shape that includes a circular shape.
Aspect 26: The method of aspect 25, wherein the first plurality of via interconnects and the second plurality of via interconnects are arranged in an interleaved manner.
Aspect 27: The method of aspects 25 through 26, wherein a first via interconnect from the first plurality of via interconnects includes a first planar area, and wherein a second via interconnect from the second plurality of via interconnects includes a second planar area that is less than the first planar area of the first via interconnect.
Aspect 28: The method of aspects 21 through 27, wherein the first dielectric layer includes a polyimide layer.
Aspect 29: The method of aspect 28, further comprising forming a plurality of pad interconnects coupled to the plurality of via interconnects.
Aspect 30: The method of aspects 28 through 29, further comprising forming a second dielectric layer that includes a different material from the first dielectric layer, wherein the second dielectric layer is coupled to the polyimide layer.
Aspect 31: The method of aspects 21 through 30, wherein the substrate is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
Aspect 32: The package of aspects 1 through 10, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
Aspect 33: The substrate of aspects 11 through 20, wherein the substrate is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
an integrated device; and
a substrate coupled to the integrated device,
wherein the substrate comprises a plurality of via interconnects, and
wherein at least one via interconnect from the plurality of via interconnects comprises a planar cross sectional shape that includes a concave portion.

2. The package of claim 1, wherein the plurality of via interconnects comprises at least one via interconnect with a concave shaped wall.

3. The package of claim 1, wherein the plurality of via interconnects comprises at least one via interconnect with a planar cross sectional shape that includes a cross shape and/or a star shape.

4. The package of claim 1, wherein the plurality of via interconnects are configured to provide at least one electrical path for power.

5. The package of claim 1,
wherein the plurality of via interconnects includes a first plurality of via interconnects, and
wherein the substrate further comprises a second plurality of via interconnects comprising at least one via interconnect with a planar cross sectional shape that includes a circular shape.

6. The package of claim 5, wherein the first plurality of via interconnects and the second plurality of via interconnects are arranged in an interleaved manner.

7. The package of claim 5,
wherein a first via interconnect from the first plurality of via interconnects includes a first planar area, and
wherein a second via interconnect from the second plurality of via interconnects includes a second planar area that is less than the first planar area of the first via interconnect.

8. The package of claim 1,
wherein the substrate includes a polyimide layer, and
wherein the plurality of via interconnects are located in the polyimide layer.

9. The package of claim 8, wherein the substrate further comprises a plurality of pad interconnects coupled to the plurality of via interconnects.

10. The package of claim 8,
wherein the substrate further comprises a dielectric layer that is a different material from the polyimide layer, and
wherein the dielectric layer is coupled to the polyimide layer.

11. A substrate comprising:
a first dielectric layer; and
a plurality of via interconnects located in the first dielectric layer, wherein at least one via interconnect from the plurality of via interconnects comprises a planar cross sectional shape that includes a concave portion.

12. The substrate of claim 11, wherein the plurality of via interconnects comprises at least one via interconnect with a concave shaped wall.

13. The substrate of claim 11, wherein the plurality of via interconnects comprises at least one via interconnect with a planar cross sectional shape that includes a cross shape and/or a star shape.

14. The substrate of claim 11, wherein the plurality of via interconnects are configured to provide at least one electrical path for power.

15. The substrate of claim 11,
wherein the plurality of via interconnects includes a first plurality of via interconnects, and
wherein the substrate further comprises a second plurality of via interconnects comprising at least one via interconnect with a planar cross sectional shape that includes a circular shape.

16. The substrate of claim 15, wherein the first plurality of via interconnects and the second plurality of via interconnects are arranged in an interleaved manner.

17. The substrate of claim 15,
wherein a first via interconnect from the first plurality of via interconnects includes a first planar area, and
wherein a second via interconnect from the second plurality of via interconnects includes a second planar area that is less than the first planar area of the first via interconnect.

18. The substrate of claim 11, wherein the first dielectric layer includes a polyimide layer.

19. The substrate of claim 18, further comprising a plurality of pad interconnects coupled to the plurality of via interconnects.

20. The substrate of claim 18, further comprising a second dielectric layer that includes a different material from the first dielectric layer, wherein the second dielectric layer is coupled to the polyimide layer.
